(19) United States
(12) Patent Application Publication
(10) Pub. No.: US 2024/0128416 A1
(43) Pub. Date: Apr. 18, 2024

(54) Panel Substrate and Method for Manufacturing Micro-LED Display Device Including the Same

(71) Applicant: LG Display Co., Ltd., Seoul (KR)

(72) Inventors: Byonghoo Kim, Paju-si (KR); Sangsoon Yoon, Paju-si (KR); Juhyuk Kim, Goyang-si (KR); Hokyeong Son, Seoul (KR); A-Ram Sohn, Paju-si (KR); Sumin Lee, Seoul (KR); Eun-Soo Chang, Paju-si (KR)

(21) Appl. No.: 18/487,788

(22) Filed: Oct. 16, 2023

(30) Foreign Application Priority Data
Oct. 17, 2022 (KR) 10-2022-0133354

(51) Int. Cl. H01L 33/58; H01L 25/16; H01L 27/12

(52) U.S. Cl. CPC H01L 33/58; H01L 25/167; H01L 27/1248

(57) ABSTRACT

A panel substrate includes a base substrate including a plurality of sub-pixel areas; a thin-film transistor disposed over each of the plurality of sub-pixel areas; an interlayer insulating film disposed over the thin-film transistor; a first optical functional layer disposed on the interlayer insulating film so as to prevent transmission and reflection of light; a second optical functional layer disposed on the first optical functional layer, wherein the second optical functional layer has first patterns and second patterns, wherein the first pattern has adhesiveness while the second pattern has less adhesiveness than the first pattern; and a plurality of micro-LEDs respectively disposed on the first patterns of the second optical functional layer.

### CROSS-REFERENCE TO RELATED APPLICATION

This application claims priority from Korean Patent Application No. 10-2022-0133354 filed on Oct. 17, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to micro-LED, and more particularly, to a panel substrate and a method for manufacturing a micro-LED display device including the panel substrate.

### Description of Related Art

A display device is applied to various electronic devices such as TVs, mobile phones, laptops and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

The micro-LED display device is resistant to the external environment, and thus does not require a protective structure such as a sealing material, and various types of materials may be used as a material of a substrate of the device. Thus, the micro-LED display device may be thinner than the organic light-emitting display device and is more advantageous in being implemented as a flexible display device. The plurality of micro-LED display devices may be arranged in a matrix manner to implement a large size display apparatus in an easier manner than a manner in which the organic-emitting display devices are arranged in a matrix manner to implement a large size display apparatus.

In the transfer technology of transferring micro-LEDs to a panel substrate, a transfer accuracy at which the micro-LED is transferred to a target position affects non-occurrence or occurrence of the defect of the display device. In other words, when the micro-LED is not transferred to the target position of the panel substrate or is incorrectly-transferred to a position out of the target position, this may lead to display device operation failure. Accordingly, there is an increasing demand for high transfer accuracy in the micro-LED transfer. Further, in order to implement a large area size display apparatus, a transfer speed in the transfer of the plurality of micro-LEDs affects productivity of the product. Thus, research on how to improve the transfer speed is ongoing.

### SUMMARY

A technical purpose according to an exemplary embodiment of the present disclosure is to provide a panel substrate that includes an optical functional layer of a multi-layer structure composed of a first optical functional layer that blocks transmission and reflection of light and prevents or reduces moisture adsorption, and a second optical functional layer that minimizes diffraction of light.

Further, a technical purpose according to an exemplary embodiment of the present disclosure is to accurately transfer a micro-LED to a target position by introducing the panel substrate including the optical functional layer of the multi-layer structure and imparting different adhering powers to different areas via a local exposure process.

Accordingly, a technical purpose according to an exemplary embodiment of the present disclosure is to prevent or reduce the micro-LED from being incorrectly-transferred or non-transferred onto the panel substrate.

Further, a technical purpose according to an exemplary embodiment of the present disclosure is to provide a method for manufacturing a micro-LED display device including the panel substrate including the optical functional layer of a multi-layer structure in which layers have different functions.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

An aspect of the present disclosure provides a panel substrate comprising: a base substrate including a plurality of sub-pixel areas; a thin-film transistor disposed over each of the plurality of sub-pixel areas; an interlayer insulating film disposed over the thin-film transistor; a first optical functional layer disposed on the interlayer insulating film so as to prevent transmission and reflection of light; a second optical functional layer disposed on the first optical functional layer, wherein the second optical functional layer has first patterns and second patterns, wherein the first pattern has adhesiveness while the second pattern has less adhesiveness than the first pattern; and a plurality of micro-LEDs respectively disposed on the first patterns of the second optical functional layer.

In another embodiment, a display device comprises a base substrate including a plurality of sub-pixel areas, a first optical functional layer including first patterns and second patterns, the first patterns having first adhesiveness and the patterns having second adhesiveness less adhesive than the first adhesiveness, the first patterns disposed alternating with and in contact with the second patterns in a lateral direction; and a plurality of micro-LEDs each disposed on a corresponding one of the first patterns of the first optical functional layer.

Another aspect of the present disclosure provides a method for manufacturing a micro-LED display device, the method comprising: forming a plurality of micro-LEDs on a growth substrate; transferring the plurality of micro-LEDs of the growth substrate to a donor substrate; preparing a panel substrate having a thin-film transistor disposed thereon; forming a first optical functional layer on the panel substrate, wherein the first optical functional layer prevents transmission and reflection of light; forming a second optical functional layer on the first optical functional layer, wherein the second optical functional layer including a material whose an adhesion force, or adhesiveness, is removed upon light being irradiated thereto; performing an exposure and developing process on the second optical functional layer to form first patterns having adhesiveness and second patterns having less adhesiveness than the first patterns; placing the donor substrate having the plurality of micro-LEDs disposed thereon onto the panel substrate; and transferring the plurality of micro-LEDs of the donor substrate onto the first patterns of the second optical functional layer of the panel substrate, respectively.

According to the aspects of the present disclosure, the optical functional layers having different functions may be disposed on the panel substrate, and the first pattern and the second pattern having different adhesiveness levels may be disposed in different areas. Thus, in the second transfer process, the micro-LED may be accurately transferred to the target position corresponding to the position of the first pattern with adhesiveness on the panel substrate. This may prevent or reduce the micro-LED from being incorrectly-transferred to a non-target location on the panel substrate or from being non-transferred to the target location.

Further, there is an advantage in that the speed of the transfer process may be improved by performing at least two second transfer processes using one donor substrate.

Further, a multi-layered optical functional layer including the first optical functional layer that blocks the transmission and reflection of light therethrough and therefrom and prevents or reduce moisture adsorption, and the second optical functional layer that minimizes the diffraction of light may be disposed on the panel substrate. Thus, a product yield and productivity may be improved.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a cross-sectional view of a display device according to an embodiment of the present disclosure.

FIG. 2 is an enlarged cross-sectional view of some components of a micro-LED as shown in FIG. 1.

FIG. 3 to FIG. 16 are diagrams illustrating a method for manufacturing a micro-LED display device according to an embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may denote the entire list of elements, may denote the individual elements of the list, or may denote any combination of the elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term or means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each embodiment of the present invention will be described with reference to the accompanying drawings.

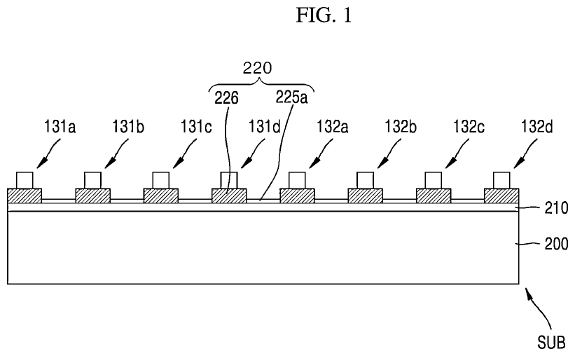

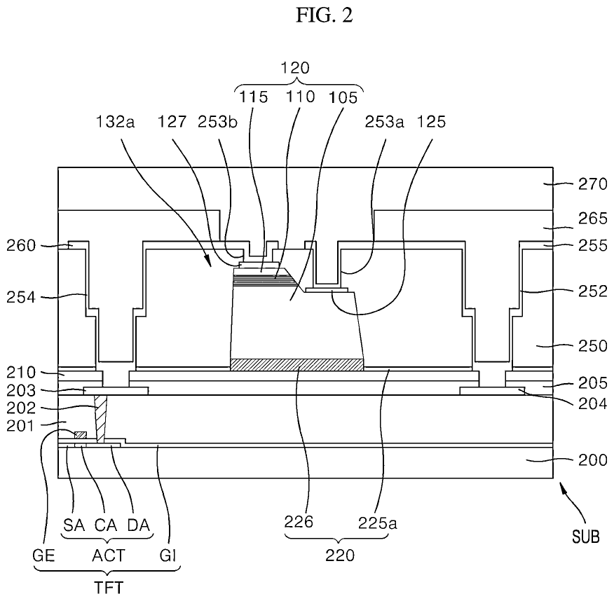

FIG. 1 is a cross-sectional view of a display device according to an exemplary embodiment of the present disclosure. FIG. 2 is an enlarged cross-sectional view of some components of a micro-LED as shown in FIG. 1.

Referring to FIG. 1 and FIG. 2, A panel substrate SUB includes a plurality of micro-LEDs 131a, 131b, 131c, and 131d, and 132a, 132b, 132c, and 132d disposed on abase substrate 200. A first optical functional layer 210 may be disposed on the base substrate 200. A second optical functional layer 220 including first patterns 226 and second patterns 225a may be disposed on the first optical functional layer 210. The plurality of micro-LEDs 131a, 131b, 131c, and 131d, and 132a, 132b, 132c, and 132d may be respectively disposed at positions corresponding to the first patterns 226 of the second optical functional layer 220.

The first optical functional layer 210 is positioned between the base substrate 200 and the plurality of micro-LEDs 131a, 131b, 131c, and 131d, and 132a, 132b, 132c, and 132d so as to prevent transmission and reflection of light therethrough and therefrom. The first optical functional layer 210 may include a material that absorbs light. In one example, the first optical functional layer 210 may include carbon black, black titanium oxide, or black iron oxide. In addition, the first optical functional layer 210 may include the light absorbing material and may further contain micro porous zeolite added to the light absorbing material. The porous zeolite contains a plurality of pores therein. Accordingly, the plurality of pores of the first optical functional layer 210 can adsorb the moisture penetrating from the interface, thereby preventing or reducing the moisture from penetrating into the display device.

The second optical functional layer 220 includes the first patterns 226 and the second patterns 225a. The first pattern 226 may have a first thickness, and the second pattern 225a may have a second thickness relatively smaller than the first thickness. Accordingly, the second optical functional layer 220 may have a stepped shape, or steps. The first patterns 226 and the second patterns 225a may be alternately arranged with each other while being disposed on the panel substrate SUB such that the second patterns 225a are disposed between the first patterns 226.

The first pattern 226 of the second optical functional layer 220 has adhesiveness, and the plurality of micro-LEDs 131a, 131b, 131c, and 131d, and 132a, 132b, 132c, and 132d may be fixed onto the panel substrate SUB, i.e. onto the base substrate 200, by this adhesiveness. Since the second pattern 225a is less adhesive than the first pattern 226, the plurality of micro-LEDs 131a, 131b, 131c, and 131d, and 132a, 132b, 132c, and 132d are not attached to the second patterns 225a. Accordingly, as the micro-LED is transferred only onto the first pattern 226 having adhesiveness, the micro-LED may be accurately transferred to a target position.

The second optical functional layer 220 may include an adhesive composite whose adhesiveness may be removed by light. In other words, the second optical functional layer 220 may include an adhesive composite which is no longer adhesive when light is irradiated thereto. In this regard, the adhesive composite may include a tackifier, a composite, a photo acid generator (PAG), and a quencher. In this regard, the quencher may include a material that neutralizes an acid generated from the photo acid generator, and, in one example, may include a basic material. For example, the quencher may include an amine-based material or a pyridine-based material. When the quencher includes the amine-based material, an example thereof may include tri(n-octyl)amine or hydroxylamine. When the quencher includes the pyridine-based material, an example thereof may include 2-benzyl pyridine, 4,4′-diphenyl 2, 2′ dipyridyl, 4-dimethyl amino pyridine, and 1,3-di(4-pyridyl)propane.

In addition, the tackifier may include a foaming agent, an antioxidant, a dendrimer, and a photoactive resin. In this regard, the photoactive resin may include novolac resin. The composite may include an alkali developable binder, a silicon (Si)-based binder, a photoinitiator, and a solvent. The photoinitiator is added, at a small amount, to the UV resin. The photoinitiator causes a polymerization reaction to start upon receiving UV light from an ultraviolet lamp. The solvent may include propylene glycol monomethyl ether acetate (PGMEA).

Hereinafter, a portion of an area in which one micro-LED 132a among the plurality of micro-LEDs 131a, 131b, 131c, and 131d, and 132a, 132b, 132c, and 132d of FIG. 1 is disposed will be described with reference to FIG. 2 as an enlarged view thereof. The portion may be referred to as a sub-pixel area. As there are a plurality of portions, it follows that there are a plurality of sub-pixel areas. Referring to FIG. 2, a thin-film transistor TFT driving the micro-LED 132a is disposed on the base substrate 200. In a larger scale, the panel substrate SUB comprises a plurality of thin-film transistors TFT, wherein each thin-film transistor TFT corresponds to a sub-pixel area of the plurality of sub-pixel areas. The base substrate 200 of the panel substrate SUB may be made of a transparent material including glass or plastic. The thin-film transistor TFT may include a semiconductor layer ACT formed on the base substrate 200, a gate electrode GE located on the semiconductor layer ACT, and a gate insulating layer GI located between the semiconductor layer ACT and the gate electrode GE. A buffer film may be further disposed between the base substrate 200 and the semiconductor layer ACT.

The semiconductor layer ACT may include channel area CA overlapping the gate electrode GE to constitute a channel, and a source area SA and a drain area DA respectively located on both opposing sides of the channel area CA. An interlayer insulating film 201 is disposed on the gate electrode GE. The interlayer insulating film 201 may receive therein a drain electrode 202 extending through the interlayer insulating film 201 and the gate insulating layer GI so as to be electrically connected to the drain area DA of the semiconductor layer ACT. Further, the interlayer insulating film 201 may receive therein a source electrode (not shown) electrically connected to the source area SA.

A connection electrode 203 and a wiring line 204 may be disposed on the interlayer insulating film 201. The connection electrode 203 and the wiring line 204 may be disposed in the same plane. In one example, the wiring line 204 may include a common voltage line. A protection layer 205 covering the connection electrode 203 and the wiring line 204 is disposed on the interlayer insulating film 201. The protection layer 205 may not cover a portion of an upper surface of each of the connection electrode 203 and the wiring line 204 to be exposed.

The optical functional layers 210 and 220 may be disposed on the protection layer 205. The optical functional layers 210 and 220 may extend through the protection layer 205 so as not to cover the portion of the upper surface of each of the connection electrode 203 and the wiring line 204 to be exposed. The optical functional layers 210 and 220 may include the first optical functional layer 210 and the second optical functional layer 220. The second optical functional layer 220 may include the first patterns 226 and the second patterns 225a. In this regard, only the first pattern 226 may have adhesiveness, while the second pattern 225a may not.

The micro-LED 132a may be disposed to overlap the first pattern 226 of the second optical functional layer 220. As the first pattern 226 has adhesiveness, the micro-LED 132a may be adhered to the first pattern 226.

The micro-LED 132a may include a light-emitting element structure 120, a first electrode 125, and a second electrode 127. The light-emitting element structure 120 may include a first semiconductor layer 105, an active layer 110 disposed on one side of a top surface of the first semiconductor layer 105, and the second semiconductor layer 115 disposed on the active layer 110. The first electrode 125 is disposed on the other side of the top surface of the first semiconductor layer 105 where the active layer 110 is not located. The second electrode 127 is disposed on the second semiconductor layer 115. In one example, in the present disclosure, an example in which the micro-LED is embodied as a horizontal or lateral type micro-LED is described for convenience of illustration. However, the present disclosure is not limited thereto. In another example, the micro-LED may be embodied as a vertical type micro-LED or a flip chip type micro-LED.

The first semiconductor layer 105 is a layer for supplying electrons to the active layer 110, and may include a nitride semiconductor containing first conductivity type impurities. For example, the first conductivity-type impurity may include an N-type impurity. The active layer 110 disposed on one side of the top surface of the first semiconductor layer 105 may have a multi-quantum well (MQW) structure. The second semiconductor layer 115 is a layer for injecting holes into the active layer 110. The second semiconductor layer 115 may include a nitride semiconductor containing second conductivity type impurities. For example, the second conductivity type impurity may include a P-type impurity.

The micro-LED 132a may be covered with a first planarization layer 250. The first planarization layer 250 may have a thickness sufficient to planarize an upper surface having a step caused by underlying circuit elements. The first planarization layer 250 may have a first contact-hole 252 and a second contact-hole 254 defined therein. The first contact-hole 252 and the second contact-hole 254 may extend through the first optical functional layer 210, the second pattern 225a of the second optical functional layer 220, and the protection layer 205 so as to expose the portion of the upper surface of each of the wiring line 204 and the connection electrode 203, respectively. Further, the first planarization layer 250 may have the third contact-hole 253a and the forth contact-hole 253b defined therein, so as to expose a portion of an upper surface of each of the first electrode 125 and the second electrode 127 of the micro-LED 132a.

The first line electrode 255 and the second line electrode 260 may be disposed on exposed surfaces of the first contact-hole 252 and the second contact-hole 254, respectively, and thus may be electrically connected to the wiring line 204 or the drain area DA of the semiconductor layer ACT of the thin-film transistor TFT, respectively. Further, the first line electrode 255 and the second line electrode 260 may be disposed on exposed surfaces of first electrode 125 and the second electrode 127, respectively, and thus the first line electrode 255 may be electrically connected to the first electrode 125. And the second line electrode 260 may be electrically connected to the second electrode 127. The first line electrode 255 and the second line electrode 260 may be made of the same material. In one example, each of the first line electrode 255 or the second line electrode 260 may include a transparent metal oxide such as indium-tin-oxide (ITO) or indium-zinc-oxide (IZO).

A bank 265 having a bank hole defined therein is disposed on the first planarization layer 250. The bank 265 is a boundary area defining the light-emitting area and plays a role in defining each sub-pixel. In one example, a remaining portion of each of the first contact-hole 252 and the second contact-hole 254 in which the first line electrode 255 and the second line electrode 260 are respectively disposed may be filled with a material constituting the bank 265. Although not shown in the drawing, a black matrix may be disposed on the bank 265. Further, a sealing layer 270 may be disposed on the base substrate 200 including the bank 265.

In an embodiment of the present disclosure, the optical functional layers having different functions may be disposed on the panel substrate, and the first pattern and the second pattern having different adhesiveness levels may be disposed in different areas. Thus, in a second transfer process, the micro-LED may be accurately transferred to the target position corresponding to the position of the first pattern with adhesiveness on the panel substrate. This may prevent or reduce the micro-LED from being incorrectly-transferred to a non-target location on the panel substrate or from being non-transferred to the target location.

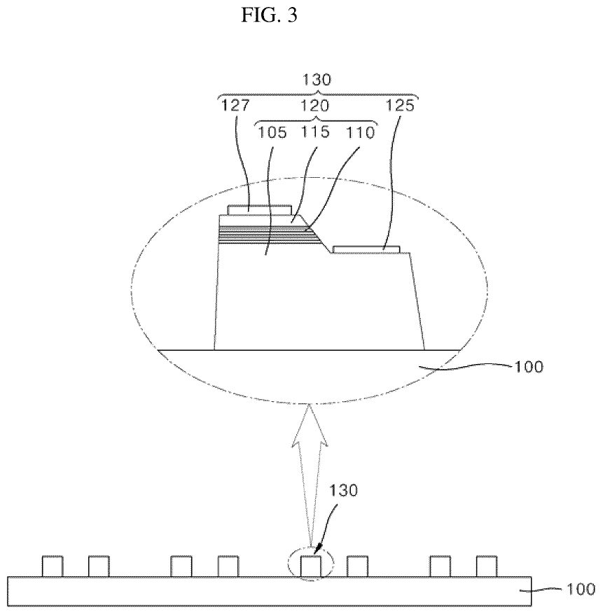

FIG. 3 to FIG. 16 are diagrams shown to illustrate a manufacturing method of a micro-LED display device according to an exemplary embodiment of the present disclosure.

Referring to FIG. 3, a plurality of micro-LEDs 130 are formed on an upper surface of a growth substrate 100. The growth substrate 100 may be made of a material such as sapphire, silicon (Si), silicon carbide (SiC), or gallium arsenide (GaAs). However, the present disclosure is not limited thereto. The micro-LED 130 formed on the growth substrate 100 may include the light-emitting element structure 120, the first electrode 125, and the second electrode 127. The light-emitting element structure 120 may include the first semiconductor layer 105, the active layer 110 disposed on one side of the upper surface of the first semiconductor layer 105, and the second semiconductor layer 115 disposed on the active layer. The first electrode 125 is disposed on the other side of the upper surface of the first semiconductor layer 105 where the active layer 110 is not located. The second electrode 127 is disposed on the second semiconductor layer 115.

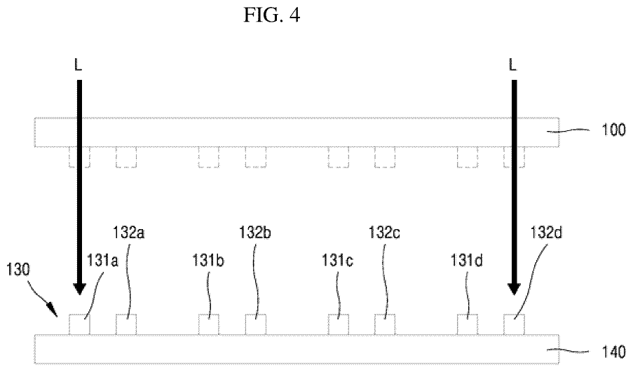

Referring to FIG. 4, a first transfer process of transferring the plurality of micro-LEDs 130 onto a donor substrate 140 is performed.

To this end, first, the growth substrate 100 on which the plurality of micro-LEDs 130 have been disposed is positioned above the donor substrate 140. The plurality of micro-LEDs 130 are disposed on the upper surface of the growth substrate 100. The growth substrate 100 may be positioned so that the plurality of micro-LEDs 130 face an upper surface of the donor substrate 140. Subsequently, laser is irradiated in a direction from a rear surface of the growth substrate 100 toward the upper surface thereof to remove the plurality of micro-LEDs 130 from the growth substrate 100 and transfer the plurality of micro-LEDs 130 onto the donor substrate 140.

The plurality of micro-LEDs 130 transferred onto the donor substrate 140 may include first transfer target micro-LEDs 131a, 131b, 131c, and 131d, and second transfer target micro-LEDs 132a, 132b, 132c, and 132d. The first transfer target micro-LEDs 131a, 131b, 131c, and 131d and the second transfer target micro-LEDs 132a, 132b, 132c, and 132d may be respectively spaced apart from each other while being disposed on one donor substrate 140.

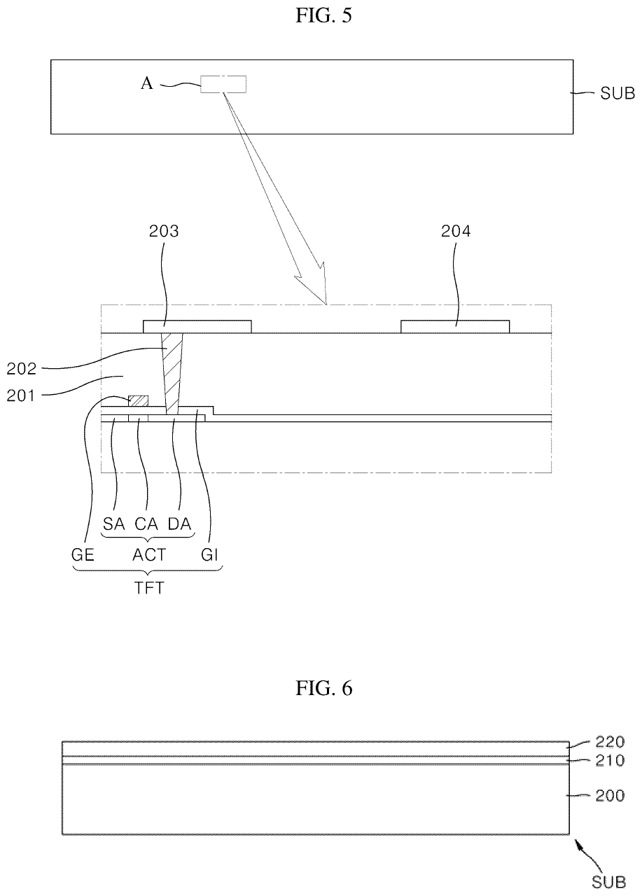

Referring to FIG. 5, the method prepares the panel substrate SUB. Circuit elements for driving the plurality of micro-LEDs to be disposed later may be disposed on the panel substrate SUB. In one example, the circuit elements may include the thin-film transistor TFT, the connection electrode 203, and the wiring line 204. A plurality of circuit elements may be arranged so as to be connected to the plurality of micro-LEDs, respectively.

Referring to an enlarged view of an area A in which one circuit element among the plurality of circuit elements is disposed, the base substrate 200 of the panel substrate SUB may include a transparent material including glass or plastic. The thin-film transistor TFT may include a semiconductor layer ACT formed on the base substrate 200, a gate electrode GE located on the semiconductor layer ACT, and a gate insulating layer GI located between the semiconductor layer ACT and the gate electrode GE. A buffer film may be further disposed between the base substrate 200 and the semiconductor layer ACT.

The semiconductor layer ACT may include channel area CA overlapping the gate electrode GE to constitute a channel, and a source area SA and a drain area DA respectively located on both opposing sides of the channel area CA. An interlayer insulating film 201 is disposed on the gate electrode GE. The interlayer insulating film 201 may receive therein a drain electrode 202 extending through the interlayer insulating film 201 and the gate insulating layer GI so as to be electrically connected to the drain area DA of the semiconductor layer ACT. Further, the interlayer insulating film 201 may receive therein a source electrode (not shown) electrically connected to the source area SA.

A connection electrode 203 and a wiring line 204 may be disposed on the interlayer insulating film 201. The connection electrode 203 and the wiring line 204 may be disposed in the same plane. In one example, the wiring line 204 may include a common voltage line. A protection layer 205 covering the connection electrode 203 and the wiring line 204 is disposed on the interlayer insulating film 201. The protection layer 205 may not cover a portion of an upper surface of each of the connection electrode 203 and the wiring line 204 so as to be exposed.

Referring to FIG. 6, the optical functional layer 210 and 220 are formed on the panel substrate SUB. The optical functional layer 210 and 220 may include a multilayer structure in which the first optical functional layer 210 and the second optical functional layer 220 are sequentially stacked.

The first optical functional layer 210 serves to prevent transmission and reflection of light therethrough and therefrom. The first optical functional layer 210 may include a material capable of absorbing light. In one example, the first optical functional layer 210 may include carbon black, black titanium oxide, or black iron oxide. In addition, the first optical functional layer 210 may include the light absorbing material and may further contain micro porous zeolite added to the light absorbing material. The porous zeolite contains a plurality of pores therein. Accordingly, the plurality of pores of the first optical functional layer 210 can adsorb the moisture penetrating from the interface, thereby preventing or reducing the moisture from penetrating into the display device.

The second optical functional layer 220 may be formed on the first optical functional layer 210 and may include an adhesive composite whose adhesiveness may be changed via light irradiated thereto. In one example, the adhesive composite may include a tackifier, a composite, a photo acid generator (PAG), and a quencher. In this regard, the quencher may include a material that neutralizes an acid generated from the photo acid generator, and, in one example, may include a basic material. For example, the quencher may include an amine-based material or a pyridine-based material. When the quencher include the amine-based material, an example thereof may include tri(n-octyl)amine or hydroxylamine. When the quencher includes the pyridine-based material, an example thereof may include 2-benzyl pyridine, 4,4′-diphenyl 2, 2′ dipyridyl, 4-dimethyl amino pyridine, and 1,3-di(4-pyridyl)propane. In addition, the tackifier may include a foaming agent, an antioxidant, a dendrimer, and a photoactive resin. In this regard, the photoactive resin may include novolac resin. The composite may include an alkali developable binder, a silicon (Si)-based binder, a photoinitiator, and a solvent. The photoinitiator is added, at a small amount, to the UV resin. The photoinitiator causes a polymerization reaction to start upon receiving UV light from an ultraviolet lamp. The solvent may include propylene glycol monomethyl ether acetate (PGMEA).

The second optical functional layer 220 includes the first patterns 226 and the second patterns 225a. The first pattern 226 may have a first thickness, and the second pattern 225a may have a second thickness relatively smaller than the first thickness. Accordingly, the second optical functional layer 220 may have a stepped shape, or steps. The first patterns 226 and the second patterns 225a may be alternately arranged with each other while being disposed on the panel substrate SUB. In other words, the second patterns 225a may be arranged between the first patterns 226, while both being disposed on the panel substrate SUB.

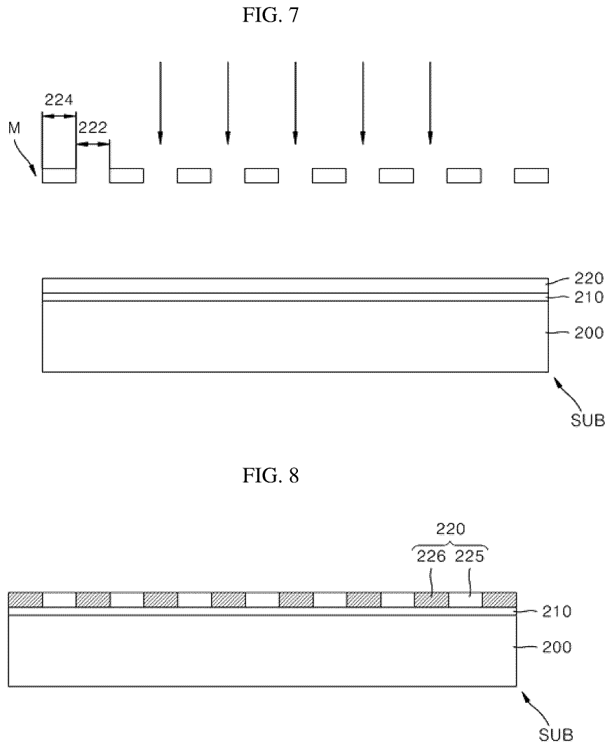

Referring to FIG. 7, an exposure mask M for an exposure process is disposed on the optical functional layer 210 and 220. The exposure mask M may have an opening 222 defined therein through which UV light is selectively irradiated, and a light-blocking portion 224 which blocks UV light. Further, UV light may be irradiated to the optical functional layer 210 and 220 through the opening 222 of the exposure mask M. In this regard, as the first optical functional layer 210 is made of a material that prevents transmission and reflection of light therethrough and therefrom but absorbs the light, the circuit elements such as the thin-film transistors located under the first optical functional layer 210 may be prevented or reduced from being affected by the light. Accordingly, a light source in the exposure process may be irradiated onto the second optical functional layer 220.

Referring to FIG. 8, since the first pattern 226 of the second optical functional layer 220 positionally corresponding to the light-blocking portion 224 of the exposure mask M of FIG. 7 is not exposed to the UV light, the adhesion force, or adhesiveness, thereof may be maintained. In contrast, a pre-second pattern 225 of the second optical functional layer 220 to which the UV light is irradiated through the opening 222 of the exposure mask M loses the adhesiveness thereof. In this regard, the photo acid generator (PAG) contained in the material constituting the second optical functional layer 220 may minimize the diffraction of light to prevent or reduce diffuse reflection of light. In other words, the photo acid generator (PAG) contained in the material constituting the second optical functional layer 220 may minimize the diffraction of light to prevent or reduce light from reaching the first pattern 226, such that the adhesive force, or adhesiveness, of only the pre-second pattern 225 is removed while the adhesive force, or adhesiveness, of the first pattern 226 is not removed.

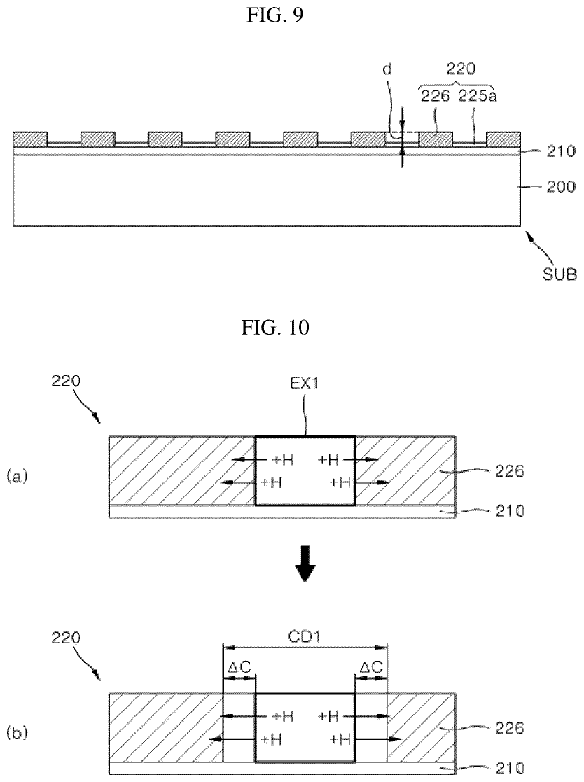

Referring to FIG. 9, the first patterns 226 and the second patterns 225a may be formed by performing a developing process on the second optical functional layer 220 subjected to the exposure process.

When the UV light is irradiated in the exposure process, the acid (+H) is generated from the photo acid generator (PAG) contained in the second optical functional layer 220 such that a difference between a solubility in a developer of the pre-second pattern 225 of the second optical functional layer 220 as the exposed portion and a solubility in the developer of the first pattern 226 as the unexposed portion may occur. That is, the exposed portion, that is, the pre-second pattern 225 dissolves well in the developer. To the contrary, the first pattern 226 does not dissolve in the developer.

As the pre-second pattern 225 is dissolved in the developing process, the second pattern 225a may be formed between adjacent first patterns 226. In this regard, the first pattern 226 may have the first thickness as the first pattern 226 is not dissolved in the developer. In contrast, the second pattern 225a has a relatively second thickness smaller than the first thickness of the first pattern 226 as the second pattern 225a is dissolved in the developer by a predetermined thickness d from an upper surface of the first pattern 226. Accordingly, the first pattern 226 has a protruding shape.

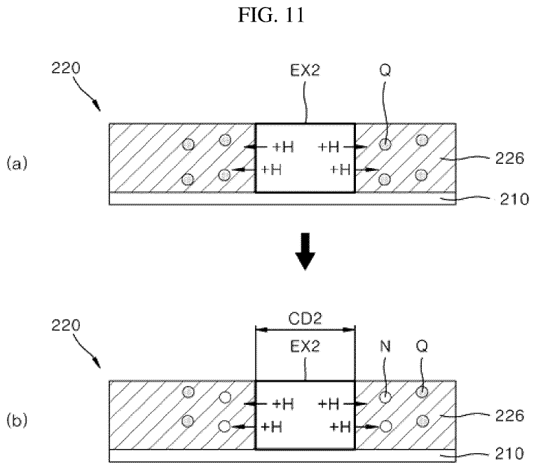

In one example, a line width of the second pattern 225a of the second optical functional layer 220 may be affected depending on whether the quencher is contained in the second optical functional layer 220. This will be described with reference to FIG. 10 and FIG. 11 below. FIG. 10 shows a case where the quencher is not contained in the second optical functional layer 220, and FIG. 11 shows a case where the quencher is contained in the second optical functional layer 220.

Referring to FIG. 10, when light is applied to an exposed area EX1 of the second optical functional layer 220, the acid (+H) is generated from the photo acid generator (PAG) contained in the second optical functional layer 220 in (a). The acid (+H) generated from the photo acid generator (PAG) causes a catalytic reaction in the exposed area EX1 of the second optical functional layer 220 such that a difference between solubility in the developer of the exposed and unexposed portions may occur. That is, the higher the concentration of the acid (+H), the higher the solubility in the developer. The exposed area EX1 may be referred to as the second pattern 225a of the second optical functional layer 220.

In this regard, the acid (+H) is not generated in the first pattern 226 of the second optical functional layer 220 to which no light is irradiated. However, the acid (+H) generated in the exposed area EX1 diffuses into the first pattern 226 of the second functional layer 220 in (b). As described above, the higher the concentration of the acid (+H), the higher the solubility in the developer. Thus, a line width CD1 may increase from a target line width by a width of an area AC into which the acid (+H) has been diffused. When the line width CD1 is greater than the target line width, an area size of a portion where the adhesive force, or adhesiveness, is maintained decreases, such that the possibility of misalignment may increase in transferring the micro-LED thereafter.

Therefore, in an embodiment of the present disclosure, the method may include a scheme for preventing or reducing the diffusion of the acid (+H) to a remaining area except for the exposed area EX1.

Specifically, as shown in FIG. 11, in the present disclosure, the quencher Q is contained in the second optical functional layer 220. The quencher Q may include a material that neutralizes the acid generated from the photo acid generator (PAG), and may include a basic material in one example.

When light is applied to the exposed area EX2 of the second optical functional layer 220 containing the quencher Q, the acid (+H) is generated from the photo acid generator (PAG) contained in a portion of the second optical functional layer 220 of the exposed area EX2 in (a). The exposed area EX2 may be referred to as the second pattern 225a of the second optical functional layer 220.

The acid (+H) is not generated in the first pattern 226 of the second optical functional layer 220 to which the light is not supplied. Further, the quencher Q neutralizes the acid (+H) at an interface between the exposed area EX2 and the first pattern 226. Accordingly, a line width CD2 after the development process may have the same width as the width of the exposed area EX2.

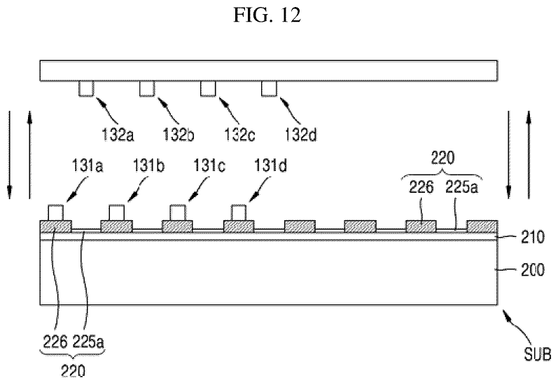

Referring to FIG. 12, the donor substrate 140 on which the plurality of micro-LEDs have been disposed is placed on the panel substrate SUB. In this regard, the plurality of micro-LEDs may include the first transfer target micro-LEDs 131a, 131b, 131c, and 131d and the second transfer target micro-LEDs 132a, 132b, 132c, and 132d.

Subsequently, the donor substrate 140 is attached to and detached from the panel substrate SUB in a stamping scheme, as indicated by arrows in FIG. 12. Then, among the plurality of micro-LEDs, the first transfer target micro-LEDs 131a, 131b, 131c, and 131d are transferred onto the panel substrate SUB. The first transfer target micro-LEDs 131a, 131b, 131c, and 131d may be respectively disposed on the first patterns 226 of the second optical functional layer having adhesiveness. In this regard, the second transfer target micro-LEDs 132a, 132b, 132c, and 132d respectively disposed adjacent to the first transfer target micro-LEDs 131a, 131b, 131c, and 131d may respectively correspond to the second patterns 225a whose the adhesiveness has been removed in the attaching process, and thus the second transfer target micro-LEDs 132a, 132b, 132c, and 132d cannot be transferred to the panel substrate SUB.

Accordingly, the micro-LED may be prevented or reduced from being incorrectly-transferred to a location other than the target location on the panel substrate SUB or from being not being transferred to the target location.

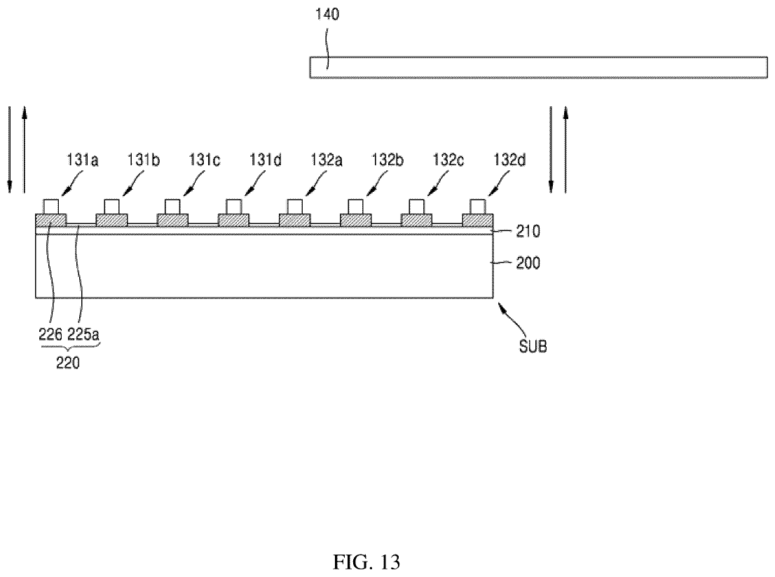

Referring to FIG. 13, the donor substrate 140 on which the second transfer target micro-LEDs 132a, 132b, 132c, and 132d have remained is attached to and detached from the panel substrate SUB in a stamping scheme as indicated by arrows in FIG. 13. Then, the second transfer target micro-LEDs 132a, 132b, 132c, and 132d are transferred onto the panel substrate SUB. The second transfer target micro-LEDs 132a, 132b, 132c, and 132d may be respectively disposed on the first patterns 226 of the second light function layer 220 having adhesiveness.

Accordingly, the first transfer target micro-LEDs 131a, 131b, 131c, and 131d and the second transfer target micro-LEDs 132a, 132b, 132c, and 132d may be disposed on the panel substrate SUB so as to overlap with the first patterns 226, respectively. In this regard, the transfer process may be repeated at least twice or more using one donor substrate 1400, such that the speed of the transfer process may be improved. Further, the transfer process of transferring the first transfer target micro-LEDs 131a, 131b, 131c, and 131d and the second transfer target micro-LEDs 132a, 132b, 132c, and 132d onto the panel substrate SUB in the stamping scheme may be performed at room temperature. This may prevent or reduced defects in the element characteristics of the micro-LED from occurring due to heat and pressure, which may otherwise occur in a scheme of transferring the micro-LEDs by applying heat and pressure.

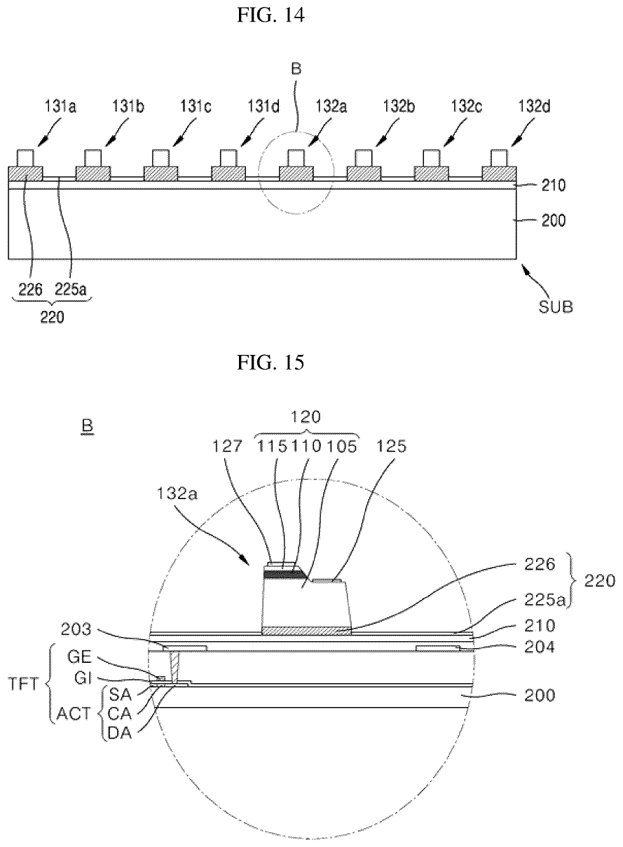

When the donor substrate 140 is removed, as shown in FIG. 14, the plurality of micro-LEDs 131a, 131b, 131c, and 131d, and 132a, 132b, 132c, and 132d may be respectively arranged in positions corresponding to the positions where the first patterns 226 of the second optical functional layer 220 are disposed. Referring to FIG. 15 as an enlarged view of some components in an area B in which one of the plurality of micro-LEDs in FIG. 14 is disposed, the micro-LED 132a may include the light-emitting element structure 120, the first electrode 125, and the second electrode 127. The first electrode 125 is disposed on the other side of the upper surface of the first semiconductor layer 105 where the active layer 110 is not located. The second electrode 127 is disposed on the second semiconductor layer 115.

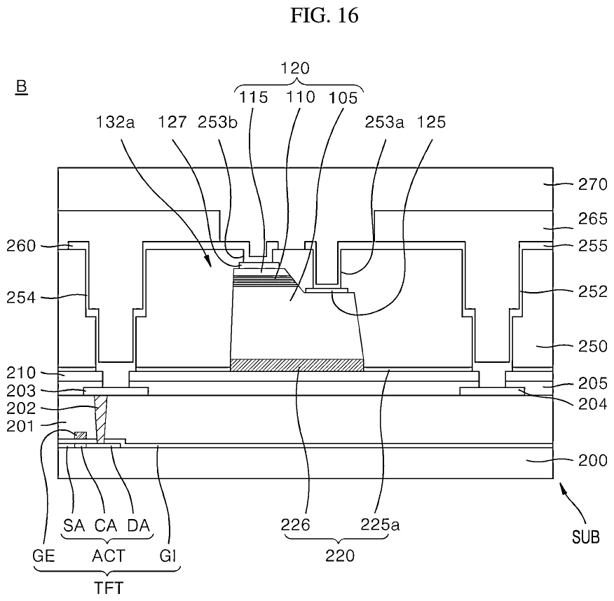

Referring to FIG. 16, the first planarization layer 250 is formed on the micro-LED 132a. The first planarization layer 250 may have a thickness sufficient to planarize an upper surface having a step caused by underlying circuit elements. The first planarization layer 250 may have the first contact-hole 252 and the second contact-hole 254 defined therein. The first contact-hole 252 and the second contact-hole 254 may extend through the first optical functional layer 210, the second pattern 225a of the second optical functional layer 220, and the protection layer 205 so as to expose the portion of the upper surface of each of the wiring line 204 and the connection electrode 203. Further, the first planarization layer 250 may have the third contact-hole 253a and the forth contact-hole 253b defined therein, so as to expose a portion of an upper surface of each of the first electrode 125 and the second electrode 127 of the micro-LED 132a.

The first line electrode 255 and the second line electrode 260 may be disposed on exposed surfaces of the first contact-hole 252 and the second contact-hole 254, respectively, and thus may be electrically connected to the wiring line 204 or the drain area DA of the semiconductor layer ACT of the thin-film transistor TFT, respectively. Further, the first line electrode 255 and the second line electrode 260 may be disposed on exposed surfaces of first electrode 125 and the second electrode 127, respectively, and thus the first line electrode 255 may be electrically connected to the first electrode 125. And the second line electrode 260 may be electrically connected to the second electrode 127. The first line electrode 255 and the second line electrode 260 may be made of the same material. In one example, each of the first line electrode 255 or the second line electrode 260 may include a transparent metal oxide such as indium-tin-oxide (ITO) or indium-zinc-oxide (IZO).

The bank 265 having the bank hole defined therein is disposed on the first planarization layer 250. The bank 265 is a boundary area defining the light-emitting area and plays a role in defining each sub-pixel. In one example, a remaining portion of each of the first contact-hole 252 and the second contact-hole 254 in which the first line electrode 255 and the second line electrode 260 are respectively disposed may be filled with a material constituting the bank 265. Although not shown in the drawing, a black matrix may be disposed on the bank 265. The sealing layer 270 is formed on the panel substrate SUB including the bank 265 to protect the micro-LED 132a from external impact or foreign materials.

In the embodiments of the present disclosure, the optical functional layer may be formed on the panel substrate, and different adhesive forces, or adhesiveness, may be imparted to the different areas in the local exposure process. Thus, in the second transfer process, the micro-LED can be accurately transferred to the target position on the panel substrate. Accordingly, the micro-LED may be prevented from being incorrectly-transferred to a non-target location on the panel substrate, or a defect that the micro-LED is not transferred to the target location may be prevented or reduced.

Although the embodiments of the present disclosure have been described in more detail with reference to the accompanying drawings, the present disclosure is not necessarily limited to these embodiments, and may be modified in a various manner within the scope of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A panel substrate comprising:
a base substrate including a plurality of sub-pixel areas;
a plurality of thin-film transistors disposed over a corresponding one of the plurality of sub-pixel areas;
an interlayer insulating film disposed over the thin-film transistor;
a first optical functional layer disposed on the interlayer insulating film so as to prevent transmission and reflection of light;
a second optical functional layer disposed on the first optical functional layer, wherein the second optical functional layer has first patterns and second patterns, wherein the first patterns have first adhesiveness while the second patterns have second adhesiveness less adhesive than the first adhesiveness; and
a plurality of micro-LEDs respectively disposed on the first patterns of the second optical functional layer.

2. The panel substrate of claim 1, wherein the first patterns of the second optical functional layer have a first thickness, and the second patterns have a second thickness smaller than the first thickness, such that the second optical functional layer has a stepped shape.

3. The panel substrate of claim 1, wherein the first patterns and the second patterns are alternately arranged with each other.

4. The panel substrate of claim 1, wherein the first optical functional layer includes:
a first material including carbon black, black titanium oxide or black iron oxide; and
a porous zeolite added to the first material.

5. The panel substrate of claim 1, wherein the second optical functional layer includes an adhesive composite whose adhesiveness is removed when light is irradiated thereto.

6. The panel substrate of claim 5, wherein the adhesive composite includes a tackifier, a composite, a photo acid generator, and a quencher.

7. The panel substrate of claim 6, wherein the quencher includes a basic material neutralizing acid generated from the photo acid generator.

8. A display device, comprising:
a base substrate including a plurality of sub-pixel areas;
a first optical functional layer including first patterns and second patterns, the first patterns having first adhesiveness and the patterns having second adhesiveness less adhesive than the first adhesiveness, the first patterns disposed alternating with and in contact with the second patterns in a lateral direction; and
a plurality of micro-LEDs each disposed on a corresponding one of the first patterns of the first optical functional layer.

9. The display device of claim 8, wherein the first pattern of the first optical functional layer has a first thickness, and the second pattern of the first optical functional has a second thickness smaller than the first thickness, such that the first pattern in contact with the second pattern forms a step.

10. The display device of claim 8, wherein the first optical functional layer includes an adhesive composite whose adhesiveness is removed when light is irradiated thereto.

11. The display device of claim 10, wherein the adhesive composite includes a tackifier, a composite, a photo acid generator, and a quencher.

12. The display device of claim 11, wherein the quencher includes a basic material neutralizing acid generated from the photo acid generator.

13. The display device of claim 8, further comprising a second optical functional layer between first optical functional layer and the base substrate, wherein the second optical functional layer includes:
a first material including carbon black, black titanium oxide or black iron oxide; and
a porous zeolite added to the first material.

14. The display device of claim 8, wherein the micro-LEDs are not disposed on the second pattern of the first optical functional layer.
